(19) United States
(12) Patent Application Publication
(10) Pub. No.: US 2020/0411341 A1
(43) Pub. Date: Dec. 31, 2020

(54) SUBSTRATE PROCESSING SYSTEM

(71) Applicant: George Xinsheng Guo, Palo Alto, CA (US)

(72) Inventor: George Xinsheng Guo, Palo Alto, CA (US)

(21) Appl. No.: 16/457,967

(22) Filed: Jun. 29, 2019

(51) Int. Cl. H01L 21/67; H01L 21/677; H01L 21/673; C23C 14/50; C23C 14/34

(52) U.S. Cl. CPC H01L 21/67196; H01L 21/67207; H01L 21/67754; H01L 21/6773; C23C 14/34; H01L 21/67201; H01L 21/67184; H01L 21/67303; C23C 14/50; H01L 21/67742

(57) ABSTRACT

The present invention provides a system of processing one or more substrates with very high efficiency. The processing system in descriptions comprises a first process chamber with various features to improve efficiency and a transfer chamber that couples to the first process chamber with various features to improve efficiency. In addition, a second process chamber and load-locks may be used to improve efficiency furthermore. This system can increases number of the substrates in processing chamber, enable multiple processes and process sequences to be carried out in the same system, and provide high throughput substrate processing.

### PRIORITY CLAIM

This application is a non-provisional utility patent application that claims the benefit of U.S. Provisional Patent Application No. 62/261,865, which was filed on Dec. 2, 2015, all of which are incorporated by reference herein in its entirety.

### BACKGROUND

The present application relates to material processing technologies, and more specifically to low cost and high throughput processing apparatus.

Material processing is widely used in photovoltaic cells and panels, window glass coating, flat panel display manufacturing, coating on flexible substrates, hard disk coating, industrial surface coating, semiconductor wafer processing, and other applications.

High volume production systems used for these applications typically comprise of interconnected box-shaped chambers that accept one or two rows of substrates. The foot print of such system is large due to the need to have multiple load locks and buffer chambers. The process sequence is determined by the hardware configuration and difficult to change in day to day operation and during research and development.

Another high volume production system used in volume processing applications is cluster tool with individual process chambers attached to a central transfer chamber with robot arms. This kind of system allow various processes and process sequence to be run in the same system, but the cost is higher due to the expense of additional large central chamber. A single robot serves all process chambers in a cluster tool, limiting the throughput of such system.

There is therefore a need for high throughput processing systems that is simpler, offers more process flexibility and has lower equipment cost.

### SUMMARY OF THE INVENTION

The present application discloses a high throughput processing apparatus that reduces equipment cost; increases number of the substrates in processing chamber, enable multiple processes and process sequences to be carried out in the same system, and provide high throughput substrate processing.

In present invention, each processing chamber has its own substrate handling arm that can pick up one or more substrates or substrate carrier from a transfer chamber, load the substrates or substrate carrier into the process chamber or scan the substrates relative to one or more processing sources inside the process chamber, and place the substrates or substrate carrier back to the transfer chamber. The handling arm can hold the substrate by gravity in case the substrate is held horizontally, by electrostatic force, or by mechanical engagement to a substrate carrier, as shown in FIG. 1A. The handling arm can have pins that can be inserted into holes on the substrate carrier as shown in FIG. 1B, where one of the substrate and its carrier is hidden for clarity. The insertion of the pins or disengagement of the pins can be accomplished by the movement of the handling arm or by movement of the substrate carrier inside the transfer chamber as shown in FIG. 1C. The substrate handling arm can then disengage with the substrate carriers and move out, shown in FIG. 1D. In case the substrate carrier is held in a tilted or vertical position, a holding force such as magnetic force or electrostatic force is applied. FIG. 1B shows one or more magnets are installed on the handling arm and the substrate carrier is either made of paramagnetic material or contains a paramagnetic material.

FIG. 2 shows the cross sectional view of a substrate handling arm inside a process chamber, where the arm can move across a processing source to improve uniformity. There can be other treatment devices such as heater, etch source in the process chamber (not shown). We use our patent pending closed loop processing source as an example in FIG. 2, where either sputtering targets or gas distribution plates forms a closed loop with optional magnetic field to enhance plasma density and uniformity. One or more conventional processing sources can also be mounted inside the process chamber to process one or more substrates at a time.

One or two process chambers can be attached to each transfer chamber, via optional gate valves, as shown in sectional view FIG. 3A, and prospective view FIG. 3B. The transfer chamber holds one or more cassettes of substrates. The cassette can move relative to the position of the substrate handling arm in the process chamber, so that the substrate handling arm can pick up different substrates from the cassette. The cassette can be placed inside the transfer chamber manually or by a cassette handling arm mounted in a vacuum load lock, shown in FIG. 3B. One or two vacuum load locks are mounted to the transfer chamber through a gate valve placed between each load lock and the transfer chamber. FIG. 3C shows two load locks are mounted to a transfer chamber to increase throughput. If more than two process chambers are used in a system, multiple transfer chambers can be attached together, each with process chambers attached to them, as shown in FIG. 3D. A cassette of substrates can be loaded from a load lock, transferred between transfer chambers, wait for substrates to be processed and returned to the cassette, and unloaded to the same load lock or a different load lock. Each process chamber can be working at all time, either processing substrates or transfer substrate and the system has a high throughput.

This system has the advantage of being scalable from one to many process chambers. The substrate handling arm can be simple and inexpensive. One axis of motion is required, if the cassette can move relative to the handling arm to load/unload the substrates. A secondary motion can be added to the handling arm for small additional cost, where the second motion engages the substrate or substrate carrier to load or unload the substrates to or from the handling arm. The substrate handling arm also serves as an optional scanning mechanism to improve the processing uniformity. There can be optional heater inside the process chamber.

The cassette in the transfer chamber can be mounted on wheels and mounted on one or more rail tracks, as shown in FIG. 4A. A chain with at least two extruded linkage can confine the cassette and move the cassette on the rail tract as shown in FIG. 4B. The chain can be attached to at least two roller chain sprockets with teeth and forms a closed loop with optional tensioner to minimize backlash during change of movement direction. One of the extruded linkages can be moved around one of the roller chain sprockets and out of the way to allow the cassette to be engaged to the cassette handling arm and move the cassette in and out of the transfer chamber. In case two or more transfer chambers are connected to each other, the cassette can be guided from one set of rail tracks to another set of rail tracks in the neighboring transfer chamber. The chains in the neighboring transfer chambers can be offset to avoid interference from each other and can work together to transfer the cassette. The extruded linkage in the neighboring transfer chamber can catch the cassette, before the extruded linkage in current transfer chamber is dis-engaged and rotated around the roller chain sprocket.

A plurality of substrates and substrate carriers can be mounted in a cassette, as shown in FIG. 5A. The cassette can be mounted to a cassette handling arm, through pins and holes or other mechanical means, as shown in FIG. 5B. Magnetic force can also be used to secure the cassette to the cassette handling arm. FIG. 5C shows two load locks are mounted to a transfer chamber and the sectional view.

During operation, a cassette is mounted to the cassette handling arm inside a load lock, the load lock is pumped down, the gate valve between load lock and transfer chamber is open, the cassette is inserted and the wheels ride on the one or more guide rails until the cassette is stopped by a extruded chain link on the chain, the chain and cassette handling arm moves the cassette together until a second extruded chain link catches the cassette. The cassette handling arm is then retracted back to the load lock and the gate valve between transfer chamber and load lock is closed. After the substrates are processed in the process chamber, the cassette is engaged to the cassette handling arm again and the chain moves the cassette until one of the extruded chain link rotates past the corresponding sprocket and out of cassette movement path. The cassette is moved out to the load lock and taken out after the load lock is vented. The procedure repeats.

Once the cassette is inside the transfer chamber, it moves so that the substrate handling arm from one of the process chamber can be inserted into the substrate carrier. The cassette just moves slightly so that the substrate handling arm can engage a substrate carrier through pins and magnetic force. The substrate handling arm retracts with the substrate carrier and carries out processing. After processing, the substrate carrier is inserted back to an empty slot in the cassette and disengages with the substrate handling arm with slight movement of the cassette.

The substrate carriers are confined to a plane parallel to the substrate handling arm movement by slots or wheels on the cassette, as shown in FIGS. 6A and 6B. The substrate carrier can sit on ramps with low friction coefficient so that the position accuracy of the substrate handling arm is not critical. To prevent the substrate carrier movement in the plane of the substrate handling arm movement, the substrate carrier can be confined by magnets mounted on the cassette and yet can break the confinement by a larger external force such as the substrate handling arm. Other means of confining the substrate carrier includes hard stops or other mechanism.

### BRIEF DESCRIPTION OF THE DRAWINGS

FIG. 1A is a perspective view of a substrate carrier with multiple substrates placed on both sides a substrate handling arm in accordance with the present invention.

FIG. 1B is a perspective view of a handling arm that can have pins that can be inserted holes on the substrate carrier.

FIG. 1C shows that the insertion of the pins or disengagement of the pins can be accomplished by the movement of the handling arm or by movement of the substrate carrier inside the transfer chamber.

FIG. 1D shows that the substrate handling arm can then disengage with the substrate carriers and move out.

FIG. 2 shows the cross sectional view of a substrate handling arm inside a process chamber, where the arm can move across a processing source to improve uniformity.

FIG. 3A shows a sectional view of one or two process chambers that can be attached to each transfer chamber, via optional gate valves.

FIG. 3B shows a prospective view of one or two process chambers that can be attached to each transfer chamber, via optional gate valves.

FIG. 3C shows a view that two load locks are mounted to a transfer chamber to increase throughput.

FIG. 3D shows a view when more than two process chambers are used in a system, multiple transfer chambers can be attached together, each with process chambers attached to them.

FIG. 4A shows that the cassette in the transfer chamber can be mounted on wheels and mounted on one or more rail tracks 401.

FIG. 4B shows that a chain 405 with at least two extruded linkage can confine the cassette and move the cassette on the rail tract.

FIG. 5A shows that a plurality of substrates and substrate carriers can be mounted in a cassette.

FIG. 5B shows that the cassette can be mounted to a cassette handling arm, through pins and holes or other mechanical means. Magnetic force can also be used to secure the cassette to the cassette handling arm.

FIG. 5C shows two load locks are mounted to a transfer chamber and the sectional view.

FIG. 6A shows an exemplary view that the substrate carriers are confined to a plane parallel to the substrate handling arm movement by slots or wheels on the cassette.

FIG. 6B shows another exemplary view that the substrate carriers are confined to a plane parallel to the substrate handling arm movement by slots or wheels on the cassette.

The substrate carrier can sit on ramps with low friction coefficient so that the position accuracy of the substrate handling arm is not critical. To prevent the substrate carrier movement in the plane of the substrate handling arm movement, the substrate carrier can be confined by magnets mounted on the cassette and yet can break the confinement by a larger external force such as the substrate handling arm. Other means of confining the substrate carrier includes hard stops or other mechanism.

In case the substrate carrier is held in a tilted or vertical position, a holding force such as magnetic force or electrostatic force is applied.

### DETAILED DESCRIPTION OF THE INVENTION AND DRAWINGS

In some embodiments, the invention describes a processing system, that comprises a first process chamber, wherein the first process chamber comprises a first deposition or processing source, a first deposition or processing mechanism, and a first substrate moving mechanism, wherein the first deposition or processing source is configured to deposit material on one or more substrates via the first deposition mechanism or process one or more substrates, wherein the first substrate moving mechanism is configured to hold the one or more substrates and move the one or more substrates in and out of the first process chamber; a transfer chamber that couples to the first process chamber, wherein the transfer chamber contains a cassette that is configured to hold one or more substrates and another substrate moving mechanism, wherein a first transfer mechanism is configured to move a substrate to or from the first process chamber to the transfer chamber, wherein the another substrate moving mechanism is configured to move the cassette relative to the first substrate moving mechanism to engage or disengage the substrate from the first substrate moving mechanism, and move the cassette in and out of the transfer chamber. In some embodiments, the system further comprises multiple process chambers and multiple transfer chambers coupled to the multiple process chambers.

In some embodiments, the processing system has the substrate that is configured to hold a vertical position.

In some embodiments, the processing system contains two substrates that are configured to be held in a substrate carrier via a holding mechanism.

In some embodiments, the processing system has a holding mechanism that is magnetic force.

In some embodiments, the processing system has a chain that is used to move the cassette, wherein the chain has two catches and each catch of the two catches can be rotated out of the way for the cassette to move out of the transfer chamber.

In some embodiments, the processing system contains a substrate carrier that is configured to be confined by one or more magnets mounted on the cassette and paramagnetic materials on the substrate carriers, and are configured to break the confinement by a larger external force.

In some embodiments, the processing system also contains a second process chamber couples to the transfer chamber, wherein a second transfer mechanism is configured to move the one or more substrates from the transfer chamber to the second process chamber, wherein the second process chamber comprises a second deposition or processing source, a second deposition or processing mechanism, and a second substrate moving mechanism, wherein the second deposition source is configured to deposit material on a substrate via the second deposition mechanism or process one or more substrates, wherein the second substrate moving mechanism is configured to hold the one or more substrates and move the one or more substrates in and out of the second process chamber.

In some embodiments, the transfer chamber couples to the first process chamber via a first gate valve, wherein the second process chamber couples to the transfer chamber via a second gate valve.

In some embodiments, the first process chamber, the transfer chamber and the second process chamber are linearly aligned.

In some embodiments, the invention describes a processing system that is comprising: a first process chamber, wherein the first process chamber comprises a first deposition or processing source, a first deposition or processing mechanism, and a first substrate moving mechanism, wherein the first deposition source is configured to deposit material on one or more substrates via the first deposition mechanism or the first processing source is configured to process one or more substrates, wherein the first substrate moving mechanism is configured to hold one or more substrates and move the one or more substrates in and out of the first process chamber; and a transfer chamber that couples to the first process chamber, wherein the transfer chamber contains a cassette that is configured to hold one or more substrates and another substrate moving mechanism, wherein a first transfer mechanism is configured to move a substrate to or from the first process chamber to the transfer chamber, wherein the another substrate moving mechanism is configured to move the cassette relative to the first substrate moving mechanism to engage or disengage the substrate from the first substrate moving mechanism, and move the cassette in and out of the transfer chamber; and one or two load locks that are connected to the transfer chamber via one or two gate valves, wherein the one or two load locks are configured to enable the cassette of substrates to be loaded in the first load lock of the one or two load locks, transferred between the first load lock to the transfer chamber, waiting for the substrates to be processed and returned to the cassette, and unloaded to the first load lock or a different load lock.

In some embodiments, the system further comprises: multiple process chambers; and multiple transfer chambers coupled to the multiple process chambers via multiple gate valves.

In some embodiments, the substrate is configured to hold a vertical position.

In some embodiments, two substrates are configured to be held in a substrate carrier via a holding mechanism.

In some embodiments, a chain is used to move the cassette, wherein the chain has two catches and each catch of the two catches can be rotated out of the way for the cassette to move out of the transfer chamber.

In some embodiments, the substrate carrier is configured to be confined by one or more magnets mounted on the cassette and paramagnetic materials on the substrate carriers, and are configured to break the confinement by a larger external force.

In some embodiments, the system is further comprising: a second process chamber that couples to the transfer chamber, wherein a second transfer mechanism configured to move the one or more substrates from the transfer chamber to the second process chamber, wherein the second process chamber comprises a second deposition or processing source, a second deposition or processing mechanism, and a second substrate moving mechanism, wherein the second deposition source is configured to deposit material on a substrate via the second deposition mechanism or the second processing source is configured to process one or more substrates, wherein the second substrate moving mechanism is configured to move the one or more substrates in and out of the second process chamber.

In some embodiments, the transfer chamber couples to the first process chamber via a first gate valve, wherein the second process chamber couples to the transfer chamber via a second gate valve.

In some embodiments, the first process chamber, the transfer chamber and the second process chamber are linearly aligned.

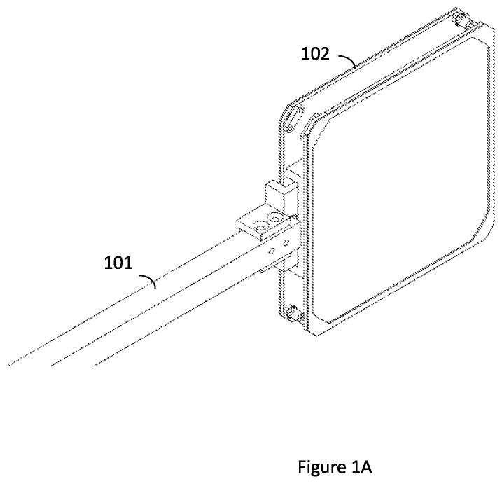

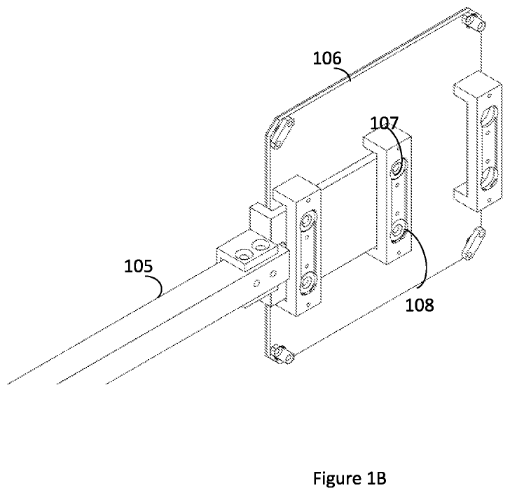

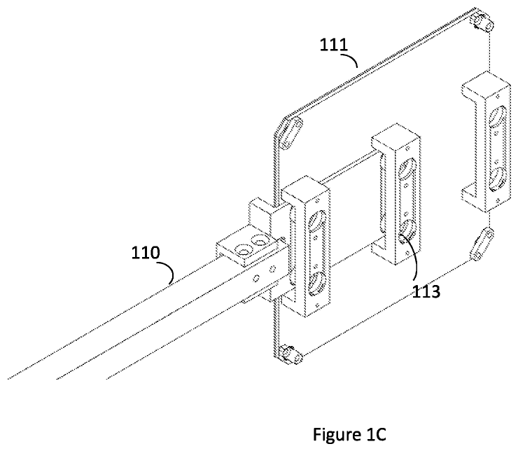

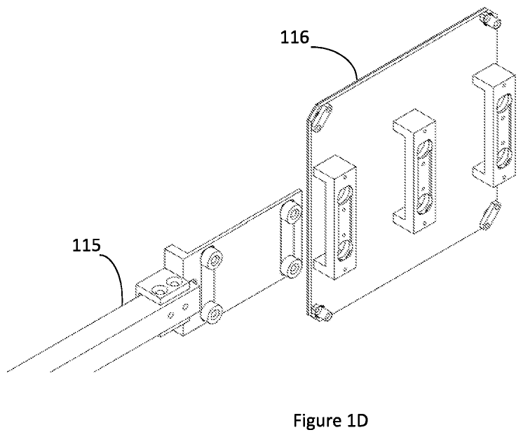

FIG. 1A is a perspective view of a substrate carrier with multiple substrates placed on both sides a substrate handling arm in accordance with the present invention. The handling arm 101 can held the substrate by gravity in case the substrate is held horizontally, by electrostatic force, or by mechanical engagement to a substrate carrier 102.

FIG. 1B is a perspective view of a handling arm 105 that can have pins 108 that can be inserted holes 107 on the substrate carrier 106, where one of the substrate and its carrier is hidden for clarity. FIG. 1B shows one or more magnets are installed on the handling arm and the substrate carrier is either made of paramagnetic material or contains a paramagnetic material.

FIG. 1C shows that the insertion of the pins 113 or disengagement of the pins can be accomplished by the movement of the handling arm 110 or by movement of the substrate carrier 111 inside the transfer chamber.

FIG. 1D show that the substrate handling arm 115 can then disengage with the substrate carriers 116 and move out.

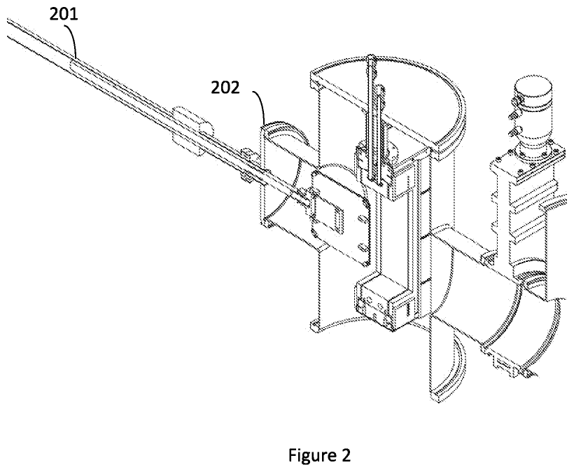

FIG. 2 shows the cross sectional view of a substrate handling arm 201 inside a process chamber 202, where the arm can move across a processing source to improve uniformity. There can be other treatment devices such as heater, etch source in the process chamber (not shown). We use our specific patent-pending closed loop processing source as an example in FIG. 2, where either sputtering targets or gas distribution plates forms a closed loop with optional magnetic field to enhance plasma density and uniformity. One or more conventional processing sources can also be mounted inside the process chamber to process one or more substrates at a time.

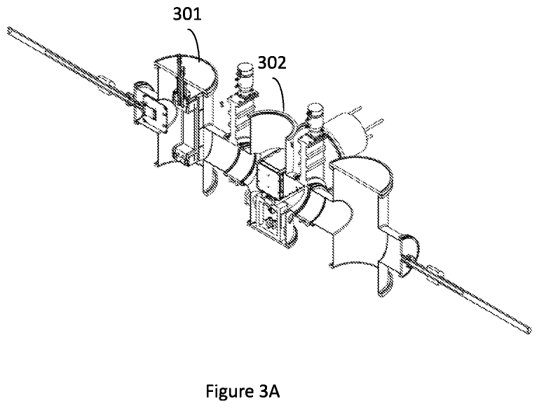

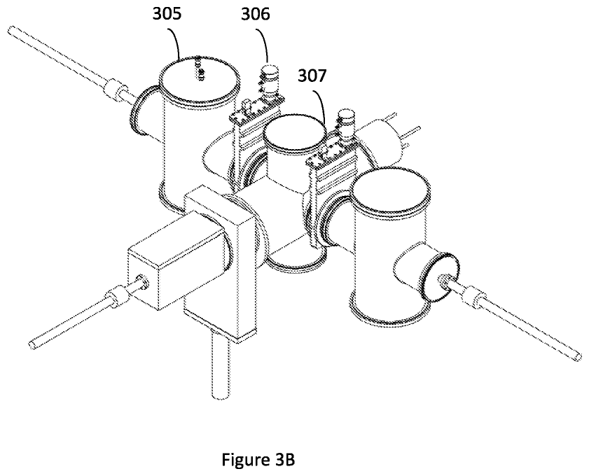

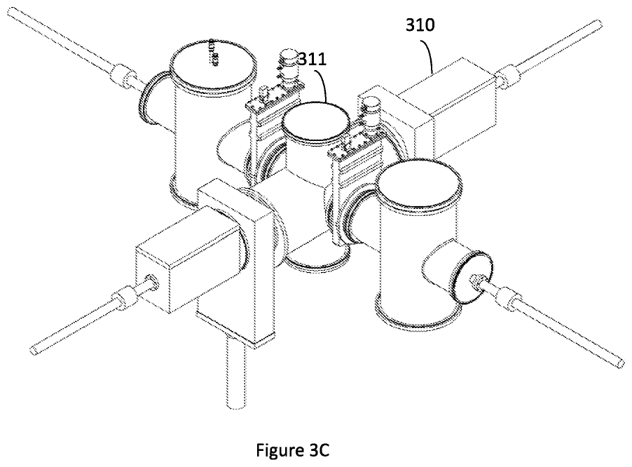

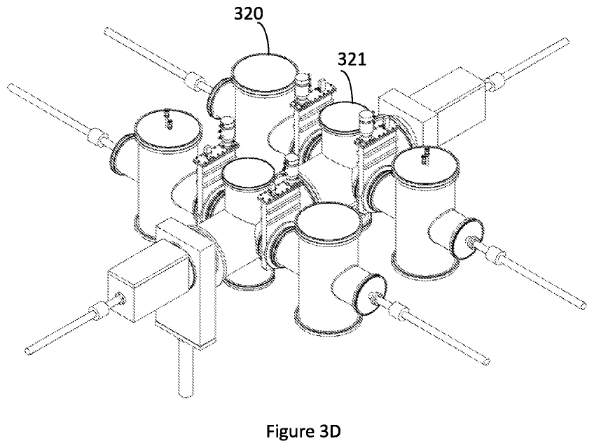

FIG. 3A shows a sectional view of one or two process chambers 301 that can be attached to each transfer chamber 302, via optional gate valves. The substrates can be transferred from one process chamber to another process chamber via the optional gate valves.

FIG. 3B shows a prospective view of one or two process chambers 305 that can be attached to each transfer chamber, via optional gate valves 306. The transfer chamber 307 holds one or more cassettes of substrates. The cassette can move relative to the position of the substrate handling arm in the process chamber, so that the substrate handling arm can pick up different substrates from the cassette. The cassette can be placed inside the transfer chamber manually or by a cassette handling arm mounted in a vacuum load lock,

FIG. 3C shows a view that two load locks 310 are mounted to a transfer chamber 311 to increase throughput.

FIG. 3D shows a view when more than two process chambers 320 are used in a system, multiple transfer chambers 321 can be attached together, each with process chambers attached to them. A cassette of substrates can be loaded from a load lock, transferred between transfer chambers, wait for substrates to be processed and returned to the cassette, and unloaded to the same load lock or a different load lock. Each process chamber can be working at all time, either processing substrates or transfer substrate and the system has a high throughput.

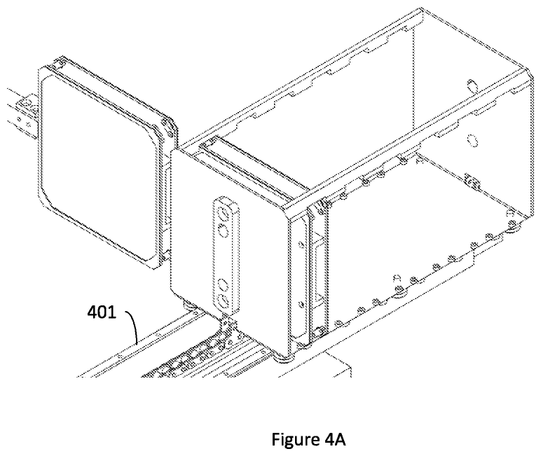

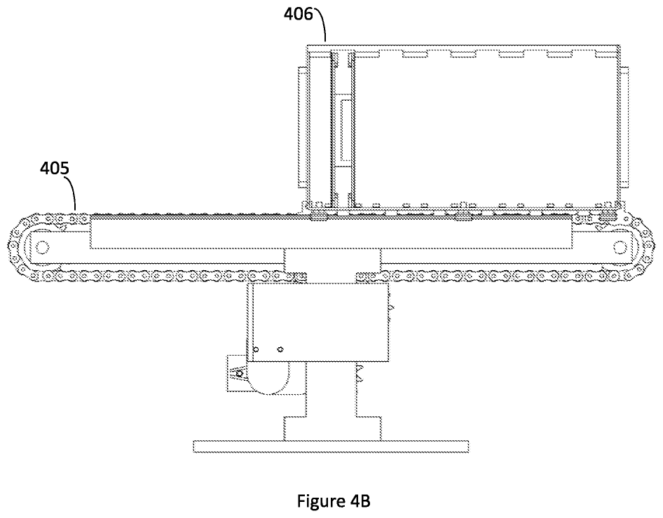

FIG. 4A shows that the cassette in the transfer chamber can be mounted on wheels and mounted on one or more rail tracks 401.

FIG. 4B shows that a chain 405 with at least two extruded linkage can confine the cassette and move the cassette 406 on the rail tract. The chain can be attached to at least two roller chain sprockets with teeth and forms a closed loop with optional tensioner to minimize backlash during change of movement direction. One of the extruded linkages can be moved around one of the roller chain sprockets and out of the way to allow the cassette to be engaged to the cassette handling arm and move the cassette in and out of the transfer chamber. In case two or more transfer chambers are connected to each other, the cassette can be guided from one set of rail tracks to another set of rail tracks in the neighboring transfer chamber. The chains in the neighboring transfer chambers can be offset to avoid interference from each other and can work together to transfer the cassette. The extruded linkage in the neighboring transfer chamber can catch the cassette, before the extruded linkage in current transfer chamber is dis-engaged and rotated around the roller chain sprocket.

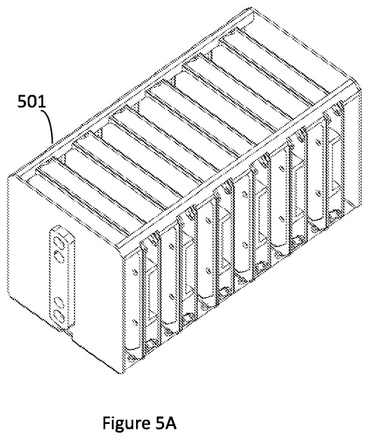

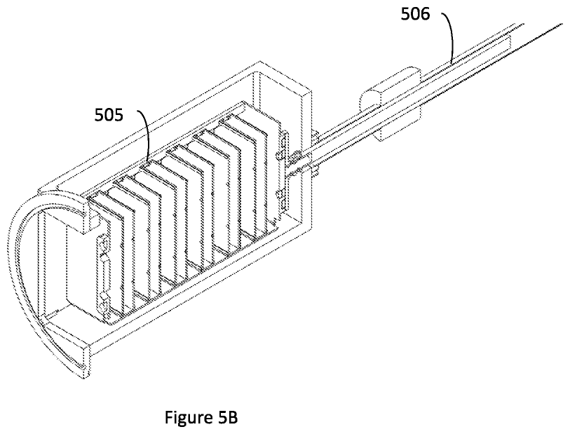

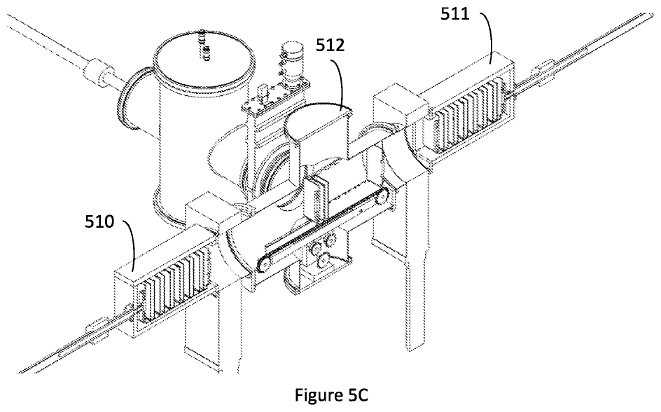

FIG. 5A shows that a plurality of substrates and substrate carriers can be mounted in a cassette 501.

FIG. 5B shows that the cassette 505 can be mounted to a cassette handling arm 506, through pins and holes or other mechanical means. Magnetic force can also be used to secure the cassette to the cassette handling arm.

FIG. 5C shows two load locks 510 and 511 are mounted to a transfer chamber 512 and the sectional view. During operation, a cassette is mounted to the cassette handling arm inside a load lock, the load lock is pumped down, the gate valve between load lock and transfer chamber is open, the cassette is inserted and rest on the one or more guide rails until the cassette is stopped by a extruded chain link on the chain, the chain and cassette handling arm moves the cassette together until a second extruded chain link catches the cassette. The cassette handling arm is then retracted back to the load lock and the gate valve between transfer chamber and load lock is closed. After the substrates are processed in the process chamber, the cassette is engaged to the cassette handling arm again and the chain moves the cassette until one of the extruded chain link rotates past the corresponding sprocket and out of cassette movement path. The cassette is moved out to the load lock and taken out after the load lock is vented. The procedure repeats.

Once the cassette is inside the transfer chamber, it moves so that the substrate handling arm from one of the process chamber can be inserted into the substrate carrier. The cassette just moves slightly so that the substrate handling arm can engage a substrate carrier through pins and magnetic force. The substrate handling arm retracts with the substrate carrier and carries out processing. After processing, the substrate carrier is inserted back to an empty slot in the cassette and disengages with the substrate handling arm with slight movement of the cassette.

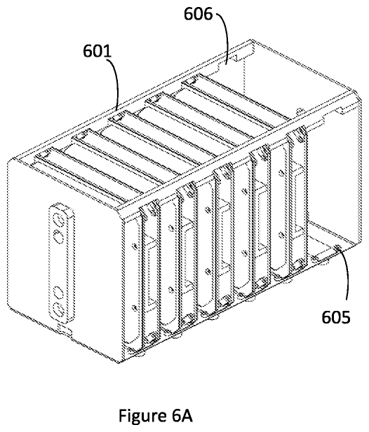

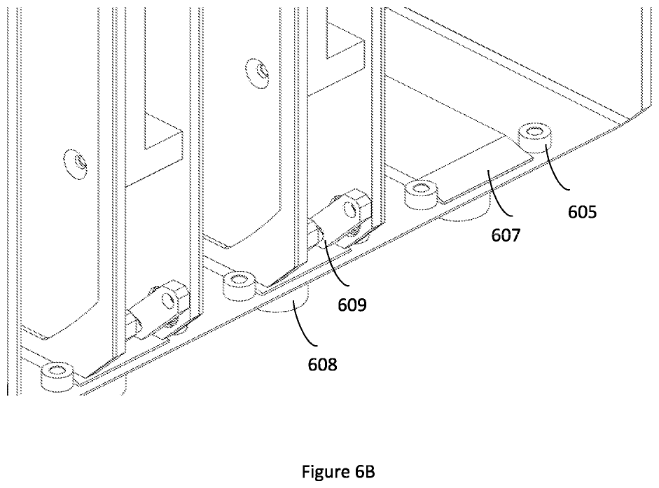

FIG. 6A shows an exemplary view that the substrate carriers are confined to a plane parallel to the substrate handling arm movement by slots 606 or wheels 605 on the cassette 601.

FIG. 6B shows another exemplary view that the substrate carriers are confined to a plane parallel to the substrate handling arm movement by slots 606 or wheels on the cassette 605.

The substrate carrier can sit on ramps 607 with low friction coefficient so that the position accuracy of the substrate handling arm is not critical. To prevent the substrate carrier movement in the plane of the substrate handling arm movement, the substrate carrier can be confined by magnets 608 mounted on the cassette and paramagnetic materials on substrate carriers 609, and yet can break the confinement by a larger external force such as the substrate handling arm. Other means of confining the substrate carrier includes hard stops or other mechanism.

What is claimed is:

1. A processing system, comprising:
a first process chamber, wherein the first process chamber comprises a first deposition or processing source, a first deposition or processing mechanism, and a first substrate moving mechanism, wherein the first deposition or processing source is configured to deposit material on one or more substrates via the first deposition mechanism or process one or more substrates, wherein the first substrate moving mechanism is configured to hold the one or more substrates and move the one or more substrates in and out of the first process chamber; and
a transfer chamber that couples to the first process chamber, wherein the transfer chamber contains a cassette that is configured to hold one or more substrates and another substrate moving mechanism, wherein a first transfer mechanism is configured to move a substrate to or from the first process chamber to the transfer chamber, wherein the another substrate moving mechanism is configured to move the cassette relative to the first substrate moving mechanism to engage or disengage the substrate from the first substrate moving mechanism, and move the cassette in and out of the transfer chamber.

2. The processing system of claim 1, further comprising:
multiple process chambers; and
multiple transfer chambers coupled to the multiple process chambers.

3. The processing system of claim 1, wherein the substrate is configured to hold a vertical position.

4. The processing system of claim 1, wherein two substrates are configured to be held in a substrate carrier via a holding mechanism.

5. The processing system of claim 4, wherein the holding mechanism is magnetic force.

6. The processing system of claim 1, wherein a chain is used to move the cassette, wherein the chain has two catches and each catch of the two catches can be rotated out of the way for the cassette to move out of the transfer chamber

7. The processing system of claim 1, wherein the substrate carrier is configured to be confined by one or more magnets mounted on the cassette and paramagnetic materials on the substrate carriers, and is configured to break the confinement by a larger external force.

8. The processing system of claim 1, further comprising:
a second process chamber couples to the transfer chamber, wherein a second transfer mechanism is configured to move the one or more substrates from the transfer chamber to the second process chamber, wherein the second process chamber comprises a second deposition or processing source, a second deposition or processing mechanism, and a second substrate moving mechanism, wherein the second deposition source is configured to deposit material on a substrate via the second deposition mechanism or process one or more substrates, wherein the second substrate moving mechanism is configured to hold the one or more substrates and move the one or more substrates in and out of the second process chamber.

9. The processing system of claim 8, wherein the transfer chamber couples to the first process chamber via a first gate valve, wherein the second process chamber couples to the transfer chamber via a second gate valve.

10. The processing system of claim 8, wherein the first process chamber, the transfer chamber and the second process chamber are linearly aligned.

11. A processing system, comprising:
a first process chamber, wherein the first process chamber comprises a first deposition or processing source, a first deposition or processing mechanism, and a first substrate moving mechanism, wherein the first deposition source is configured to deposit material on one or more substrates via the first deposition mechanism or the first processing source is configured to process one or more substrates, wherein the first substrate moving mechanism is configured to hold one or more substrates and move the one or more substrates in and out of the first process chamber;
a transfer chamber that couples to the first process chamber, wherein the transfer chamber contains a cassette that is configured to hold one or more substrates and another substrate moving mechanism, wherein a first transfer mechanism is configured to move a substrate to or from the first process chamber to the transfer chamber, wherein the another substrate moving mechanism is configured to move the cassette relative to the first substrate moving mechanism to engage or disengage the substrate from the first substrate moving mechanism, and move the cassette in and out of the transfer chamber; and
one or two load locks that are connected to the transfer chamber via one or two gate valves, wherein the one or two load locks are configured to enable the cassette of substrates to be loaded in the first load lock of the one or two load locks, transferred between the first load lock to the transfer chamber, waiting for the substrates to be processed and returned to the cassette, and unloaded to the first load lock or a different load lock.

12. The processing system of claim 11, further comprising:
multiple process chambers; and
multiple transfer chambers coupled to the multiple process chambers via multiple gate valves.

13. The processing system of claim 11, wherein the substrate is configured to hold a vertical position.

14. The processing system of claim 11, wherein two substrates are configured to be held in a substrate carrier via a holding mechanism.

15. The processing system of claim 11, wherein a chain is used to move the cassette, wherein the chain has two catches and each catch of the two catches can be rotated out of the way for the cassette to move out of the transfer chamber.

16. The processing system of claim 15, wherein the substrate carrier is configured to be confined by one or more magnets mounted on the cassette and paramagnetic materials on the substrate carriers, and is configured to break the confinement by a larger external force.

17. The processing system of claim 11, further comprising:
a second process chamber that couples to the transfer chamber, wherein a second transfer mechanism configured to move the one or more substrates from the transfer chamber to the second process chamber, wherein the second process chamber comprises a second deposition or processing source, a second deposition or processing mechanism, and a second substrate moving mechanism, wherein the second deposition source is configured to deposit material on a substrate via the second deposition mechanism or the second processing source is configured to process one or more substrates, wherein the second substrate moving mechanism is configured to move the one or more substrates in and out of the second process chamber.

18. The processing system of claim 17, wherein the transfer chamber couples to the first process chamber via a first gate valve, wherein the second process chamber couples to the transfer chamber via a second gate valve.

19. The processing system of claim 17, wherein the first process chamber, the transfer chamber and the second process chamber are linearly aligned.
